(19) United States
(12) Patent Application Publication
(10) Pub. No.: US 2008/0173895 A1
(43) Pub. Date: Jul. 24, 2008

(54) Gallium nitride on silicon with a thermal expansion transition buffer layer

(75) Inventors: Jer-Shen Maa, Vancouver, WA (US); Tingkai Li, Vancouver, WA (US); Douglas J. Tweet, Camas, WA (US); Gregory M. Stecker, Vancouver, WA (US); Sheng Teng Hsu, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/657,149

(22) Filed: Jan. 24, 2007

(51) Int. Cl. H01L 29/267; H01L 21/20

(52) U.S. Cl. 257/191; 438/495; 257/76; 257/200; 257/E29.081; 257/E21.119

(57) ABSTRACT

A method is provided for forming a matching thermal expansion interface between silicon (Si) and gallium nitride (GaN) films. The method provides a (111) Si substrate with a first thermal expansion coefficient (TEC), and forms a silicon-germanium (SiGe) film overlying the Si substrate. A buffer layer is deposited overlying the SiGe film. The buffer layer may be aluminum nitride (AlN) or aluminum-gallium nitride (AlGaN). A GaN film is deposited overlying the buffer layer having a second TEC, greater than the first TEC. The SiGe film has a third TEC, with a value in between the first and second TECs. In one aspect, a graded SiGe film may be formed having a Ge content ratio in a range of about 0% to 50%, where the Ge content increases with the graded SiGe film thickness.

### BACKGROUND OF THE INVENTION

1. Field of the Invention

This invention generally relates to integrated circuit (IC) fabrication and, more particularly, to a gallium nitride/silicon (Si) thermal expansion interface and associated fabrication process.

2. Description of the Related Art

Gallium nitride (GaN) is a Group III/Group V compound semiconductor material with wide bandgap (3.4 eV), which has optoelectronic, as well as other applications. Like other Group III nitrides, GaN has a low sensitivity to ionizing radiation, and so, is useful in solar cells. GaN is also useful in the fabrication of blue light-emitting diodes (LEDs) and lasers. Unlike previous indirect bandgap devices (e.g., silicon carbide), GaN LEDs are bright enough for daylight applications. GaN devices also have application in high power and high frequency devices, such as power amplifiers.

GaN LEDs are conventionally fabricated using a metalorganic chemical vapor deposition (MOCVD) for deposition on a sapphire substrate. Zinc oxide and silicon carbide (SiC) substrate are also used due to their relatively small lattice constant mismatch. However, these substrates are expensive to make, and their small size also drives fabrication costs. For example, the state-of-the-art sapphire wafer size is relatively small when compared to silicon wafers. The most commonly used substrate for GaN-based devices is sapphire. The low thermal and electrical conductivity constraints associated with sapphire make device fabrication more difficult. For example, all contacts must be made from the top side. This contact configuration complicates contact and package schemes, resulting in a spreading-resistance penalty and increased operating voltages. The poor thermal conductivity of sapphire, as compared with that of Si or SiC, also prevents efficient dissipation of heat generated by high-current devices, such as laser diodes and high-power transistors, consequently inhibiting device performance.

To minimize costs, it would be desirable to integrate GaN device fabrication into more conventional Si-based IC processes, which has the added cost benefit of using large-sized (Si) wafers. Si substrates are of particular interest because they are less expansive and they permit the integration of GaN-based photonics with well-established Si-based electronics. The cost of a GaN heterojunction field-effect transistor (HFET) for high frequency and high power application could be reduced significantly by replacing the expensive SiC substrates that are conventionally used.

FIG. 1 is a graph depicting the lattice constants of GaN, Si, SiC, AlN and sapphire (prior art). There are two fundamental problems associated with GaN-on-Si device technology. First, there is a lattice mismatch between Si and GaN. The difference in lattice constants between GaN and Si, as shown in the figure, results in a high density of defects from the generation of threading dislocations. This problem is addressed by using a buffer layer of AMN, InGaN, AlGaN, or the like, prior to the growth of GaN. The buffer layer provides a transition region between the GaN and Si.

FIG. 2 is a graph depicting the thermal expansion coefficients (TECs) of GaN, Si, SiC, AlN, and sapphire (prior art). An additional and more serious problem exists with the use of Si, as there is also a thermal mismatch between Si and GaN. GaN-on-sapphire experiences a compressive stress upon cooling. Therefore, film cracking is not as serious of an issue as GaN-on-Si, which is under tensile stress upon cooling, causing the film to crack when the film is cooled down from the high deposition temperature. The thermal expansion coefficient mismatch between GaN and Si is about 54%.

The film cracking problem has been analyzed in depth by various groups, and several methods have been tested and achieve different degrees of success. The methods used to grow crack-free layers can be divided into two groups. The first method uses a modified buffer layer scheme. The second method uses an in-situ silicon nitride masking step. The modified buffer layer schemes include the use of a graded AlGaN buffer layer, AlN interlayers, and AlN/GaN or AlGaN/GaN-based superlattices.

Although the lattice buffer layer may absorb part of the thermal mismatch, the necessity of using temperatures higher than 1000° C. during epi growth and other device fabrication processes may cause wafer deformation. The wafer deformation can be reduced with a very slow rate of heating and cooling during wafer processing, but this adds additional cost to the process, and doesn't completely solve the thermal stress and wafer deformation issues.

It is generally understood that a buffer layer may reduce the magnitude of the tensile growth stress and, therefore, the total accumulated stress. However, from FIG. 2 it can be seen that there is still a significant difference in the TEC of these materials, as compared with GaN. Therefore, thermal stress remains a major contributor to the final film stress.

It would be advantageous if the thermal mismatch problem associated with GaN-on-Si device technology could be practically eliminated without using slow heating and cooling processes.

It would be advantageous if the TEC of the buffer layer used in GaN-on-Si structures could be modified to match the thermal expansion coefficient of the GaN, as well as a Si substrate, to further reduce the thermal stresses.

### SUMMARY OF THE INVENTION

The present invention provides a means for matching the TEC of a Si substrate with that of a GaN film deposited on the Si substrate. The TEC of the Si substrate is modified by depositing a layer structure on Si, which has a TEC that more closely matches the TEC of the GaN film. Although the difference in TEC between GaN and Si is quite large, the surface TEC of the Si wafer can be modified by depositing films with higher TEC values. The TEC interface film is compatible with Si and IC process steps, and the TEC of this film can be adjusted to a desired value.

Accordingly, a method is provided for forming a matching thermal expansion interface between silicon (Si) and gallium nitride (GaN) films. The method provides a (111) Si substrate with a first thermal expansion coefficient (TEC), and forms a silicon-germanium (SiGe) film overlying the Si substrate. A buffer layer is deposited overlying the SiGe film. The buffer layer may be aluminum nitride (AlN) or aluminum-gallium nitride (AlGaN). A GaN film is deposited overlying the buffer layer having a second TEC, greater than the first TEC. The SiGe film has a third TEC, with a value in between the first and second TECs.

In one aspect, a non-varying Ge content SiGe film is formed, with a Ge content in the range of about 10 to 50%, and a thickness in a range of about 100 to 500 nm. In this aspect, the Ge content may be selected so as to make the SiGe TEC about midway between the first and second TECs. Alternately, a graded SiGe film may be formed having a Ge content ratio in a range of about 0% to 50%, where the Ge content increases with the graded SiGe film thickness. For example, the graded SiGe film may have a bottom layer with a TEC about equal to the first (Si) TEC, and a top layer with a TEC about equal to the second (GaN) TEC.

In another aspect, a SiGe film may be formed with a relaxed top layer of SiGe. For example, the method may implant helium or hydrogen ions into the SiGe film.

Additional details of the above-described method and a GaN-on-Si structure with a thermal expansion interface are provided below.

### BRIEF DESCRIPTION OF THE DRAWINGS

FIG. 1 is a graph depicting the lattice constants of GaN, Si, SiC, AlN and sapphire (prior art).

FIG. 2 is a graph depicting the thermal expansion coefficients (TECs) of GaN, Si, SiC, AlN, and sapphire (prior art).

FIG. 3 is a partial cross-sectional view of a gallium nitride (GaN)-on-silicon (Si) structure with a thermal expansion interface.

FIG. 4 is a partial cross-sectional view depicting a first variation of the structure of FIG. 3.

FIG. 5 is a partial cross-sectional view depicting a second variation of the structure of FIG. 3.

FIG. 6 is a partial cross-sectional view depicting a third variation of the structure of FIG. 3.

FIG. 7 is a graph depicting the TEC of SiGe films as a function of Ge content.

FIG. 8 is a graph depicting the melting point of SiGe films as a function of Ge content.

FIGS. 9 through 12 depict steps in the fabrication of the structures depicted in FIGS. 3 through 6.

FIG. 13 is a flowchart illustrating a method for forming a matching thermal expansion interface between Si and GaN films.

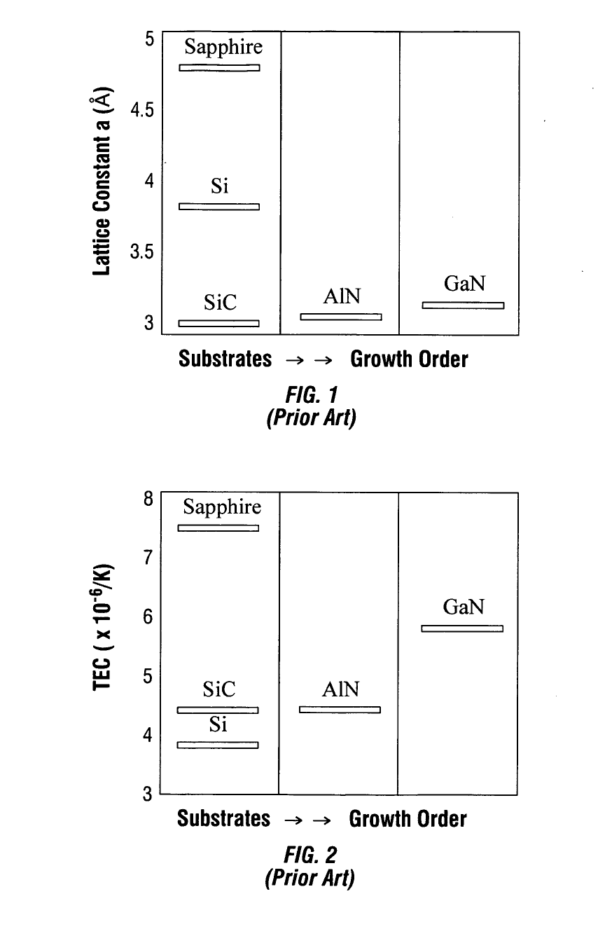

### DETAILED DESCRIPTION

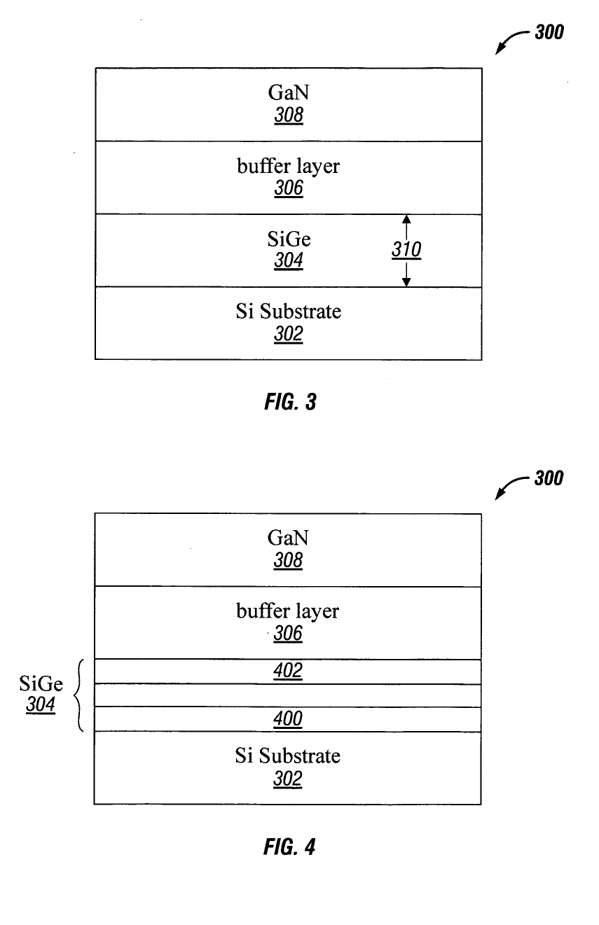

FIG. 3 is a partial cross-sectional view of a gallium nitride (GaN)-on-silicon (Si) structure with a thermal expansion interface. The structure 300 comprises a (111) Si substrate 302 with a first thermal expansion coefficient (TEC). A silicon-germanium (SiGe) film 304 overlies the Si substrate 302. A buffer layer 306 overlies the SiGe film 304. For example, the buffer layer 306 may be either aluminum nitride (AlN) or aluminum-gallium nitride (AlGaN). However, other buffer layer materials are known in the art, that although less desirable in some circumstances, may also be used. A GaN film 308 overlies the buffer layer 306, having a second TEC. The SiGe film 304 has a third TEC, with a value in between the first and second TECs.

Generally, the SiGe film 304 may have a thickness 310 in the range of about 200 nanometers (nm) to 4 micrometers. In one aspect, the SiGe film 304 has a non-varying Ge content in a range of about 10 to 50%, and a thickness 310 in a range of about 100 to 500 nm. In this aspect, the Ge content may be selected so that the TEC of the SiGe film 304 is approximately midway between the TEC of GaN and Si.

FIG. 4 is a partial cross-sectional view depicting a first variation of the structure of FIG. 3. In this aspect, the SiGe film 304 is a graded SiGe film with a Ge content that increases with the graded SiGe film thickness, where the Ge content ratio in a range of about 0% to 50%. Alternately stated, the Ge content of the SiGe film 304 is at a minimum at the interface with the Si substrate 302, and at a maximum at the interface with the GaN film 308.

For example, the graded SiGe film 304 may have a bottom layer 400 with a TEC about equal to the first TEC. Likewise, the graded SiGe film 304 may have a top layer 402 with a TEC about equal to the second TEC. That is, the graded SiGe top layer 402 has a TEC responsive to the Ge content in the graded SiGe, and the Ge content is varied to achieve the desired TEC.

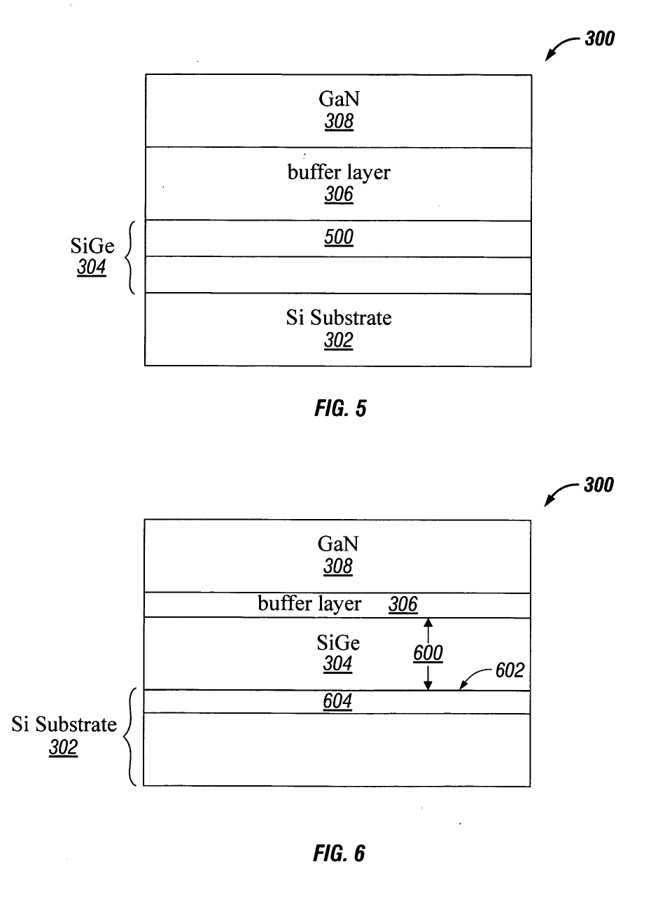

FIG. 5 is a partial cross-sectional view depicting a second variation of the structure of FIG. 3. The SiGe film 304 includes a relaxed top layer 500 of SiGe. Note: in this aspect, the SiGe film 304 may be graded, as in FIG. 4, or have a constant Ge content, as in FIG. 3.

FIG. 6 is a partial cross-sectional view depicting a third variation of the structure of FIG. 3. In this aspect, the entire the SiGe film 304 is a relaxed SiGe film having a thickness 600 in the range of about 200 nm to 500 nm. The Si substrate 302 has a top surface 602 and an ion implantation-induced structurally damaged layer 604 in the range of about 10 to 30 nm below the Si substrate top surface 602. Note: in this aspect, the SiGe film 304 may be graded, as in FIG. 4, or have a constant Ge content, as in FIG. 3. Typically, the SiGe film 304 has a constant Ge content, since the film is thin in this aspect of the structure.

### Functional Description

As noted above, the present invention structure matches the TEC of a Si substrate to that of an overlying GaN film. The TEC of Si substrate is modified by depositing a TEC interface layer structure on the Si substrate with TEC that more closely matches the TEC of GaN. The TEC of SiGe is compatible with Si and general IC processes, and the TEC of this film can be adjusted to a desired value.

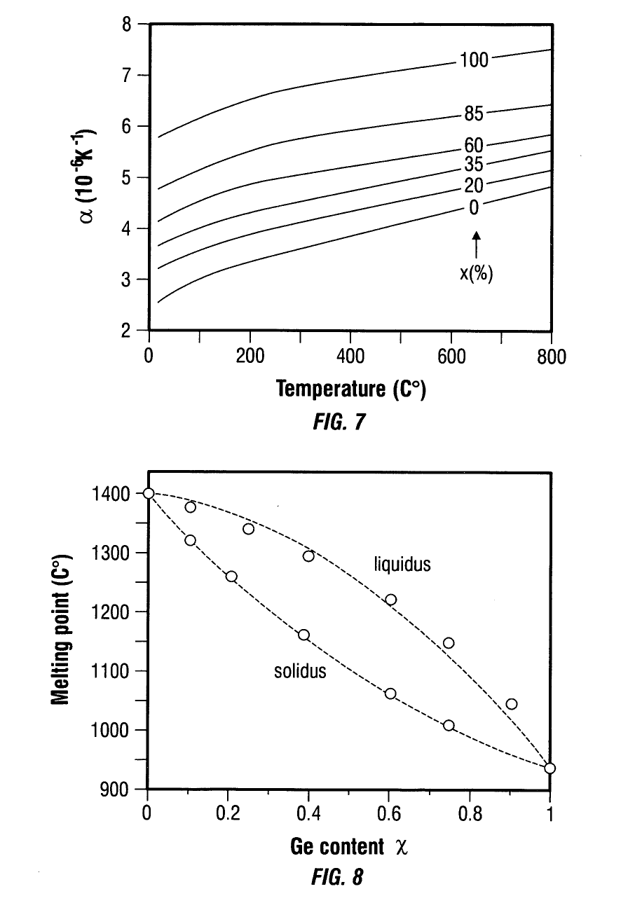

FIG. 7 is a graph depicting the TEC of SiGe films as a function of Ge content. The invention is built upon the understanding that Ge has a TEC that is very close to GaN, and that the TEC of SiGe is proportional to the Ge concentration. It is also possible to form a film with a TEC gradient by depositing SiGe film with a Ge concentration gradient that varies with the SiGe film thickness (depth). Alternately stated, the SiGe film is used to adjust the surface TEC of Si substrate. Since the difference in TEC between GaN and the surface of the Si substrate is reduced, the problem of film cracking during cooling is resolved.

FIG. 8 is a graph depicting the melting point of SiGe films as a function of Ge content. Typically, a Ge content is selected so that the melting point of SiGe film is above the GaN deposition temperature. From FIG. 8, it can be seen that up to about 40% Ge content, the melting point of a SiGe film is still above 1150° C.

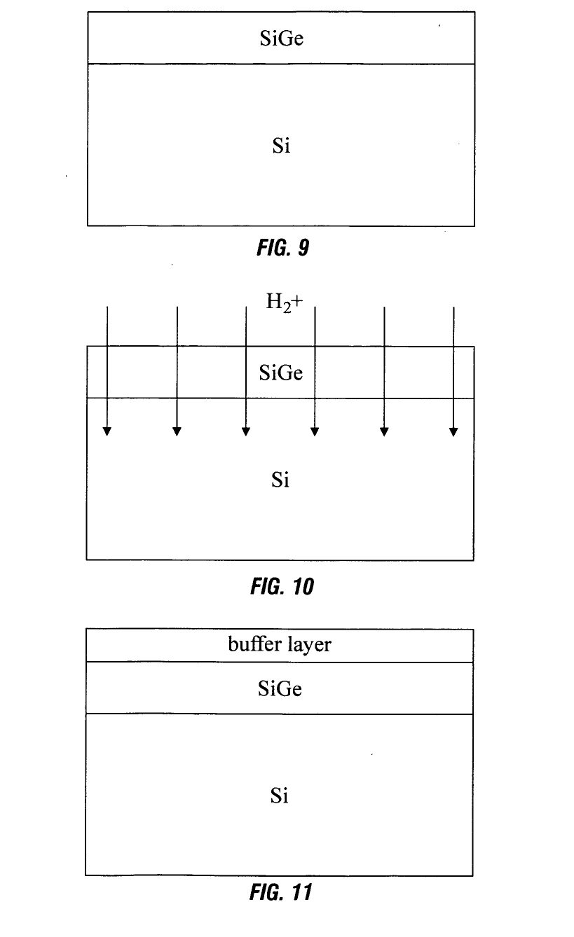

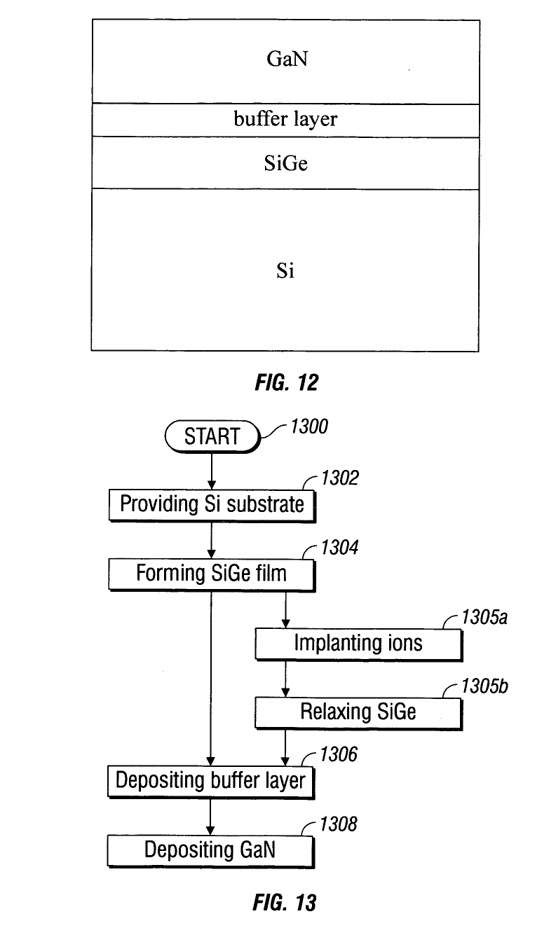

FIGS. 9 through 12 depict steps in the fabrication of the structures depicted in FIGS. 3 through 6. The exemplary process is as follows.

1. Deposit a SiGe film on a (111) Si substrate, by chemical vapor deposition (CVD) or molecular beam epitaxy (MBE). The (111) crystallographic orientation of the Si matches the GaN Wurtzite structure.

The film thickness range is from 200 nm to 4 gm. The Ge ratio is from 0% to 50%. The top layer is relaxed SiGe film with a higher Ge content. See FIG. 9.

2. Optionally, a SiGe film thickness of 200 nm to 500 nm is formed. The SiGe film is relaxed by hydrogen or helium implantation, and annealing, as described in U.S. Pat. No. 6,562,703, which is incorporated herein by reference. See FIG. 10.

3. Deposit an AlN or AlGaN buffer layer by metalorganic CVD (MOCVD), hydride vapor phase epitaxy (HVPE), or MBE. See FIG. 11.

4. Deposit of GaN by MOCVD, HVPE, or MBE.

FIG. 13 is a flowchart illustrating a method for forming a matching thermal expansion interface between Si and GaN films. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1300.

Step 1302 provides a (111) Si substrate with a first TEC. Step 1304 forms a SiGe film overlying the Si substrate. Typically, the SiGe film has a thickness in the range of about 200 nm to 4 micrometers. Step 1306 deposits a buffer layer overlying the SiGe film, such as AlN or AlGaN. The buffer layer may be deposited using a process such as MOCVD, HVPE, or MBE. In one aspect, the SiGe film includes a relaxed top layer of SiGe. The SiGe may be relaxed as a response to ion implantation or a sufficiently high Ge content in the SiGe film. Step 1308 deposits a GaN film overlying the buffer layer having a second TEC, greater than the first TEC. Likewise, the GaN film may be deposited using a MOCVD, HVPE, or MBE process. The SiGe film formed in Step 1304 has a third TEC, with a value in between the first and second TECs.

In one aspect, forming the SiGe film in Step 1304 includes forming a SiGe film with a non-varying Ge content in a range of about 10 to 50%, and a thickness in a range of about 100 to 500 nm. In this aspect, the TEC of SiGe is likewise non-varying and typically selected to be about midway between the TEC of Si and GaN.

In another aspect, Step 1304 forms a graded SiGe film having a Ge content ratio in a range of about 0% to 50%, where the Ge content increases with the graded SiGe film thickness. The graded SiGe film has a TEC responsive to the Ge content in the graded SiGe film. For example, Step 1304 may include forming a graded SiGe film with a bottom layer having a TEC about equal to the first TEC. Likewise, Step 1304 may include forming a graded SiGe film with a top layer having a TEC about equal to the second TEC.

In a different aspect, Step 1304 forms a SiGe film having a thickness in a range of about 200 nm to 500 nm. In this aspect the method includes additional steps. Step 1305a implanting ions into the SiGe film, such as helium or hydrogen ions. Step 1305b relaxes the SiGe film in response to the ion implantation. For example, implanting ions into the SiGe film in Step 1305a may include implanting H₂⁺ with a dosage in the range of 2×10¹⁴ cm⁻² to 2×10¹⁶ cm⁻², and an energy in the range of about 10 keV to 100 keV.

A GaN-on-Si structure with a TEC interface has been provided, along with an associated fabrication process. Examples of particular materials and process steps have been given to illustrate the invention. However, the invention is not necessarily limited to these examples. Other variations and embodiments of the invention will occur to those skilled in the art.

We claim:

1. A method for forming a matching thermal expansion interface between a silicon (Si) film and a gallium nitride (GaN) film, the method comprising:
providing a (111) Si substrate with a first thermal expansion coefficient (TEC);
forming a silicon-germanium (SiGe) film overlying the Si substrate;
depositing a buffer layer overlying the SiGe film, selected from a group consisting of aluminum nitride (AlN) and aluminum-gallium nitride (AlGaN);
depositing a GaN film overlying the buffer layer having a second TEC, greater than the first TEC; and,
wherein the SiGe film has a third TEC, with a value in between the first and second TECs.

2. The method of claim 1 wherein forming the SiGe film includes forming a SiGe film having a thickness in a range of about 200 nanometers (nm) to 4 micrometers.

3. The method of claim 1 wherein forming the SiGe film includes forming a SiGe film with a non-varying Ge content in a range of about 10 to 50%, and a thickness in a range of about 100 to 500 nm.

4. The method of claim 1 wherein forming the SiGe film includes forming a graded SiGe film having a Ge content ratio in a range of about 0% to 50%, where the Ge content increases with the graded SiGe film thickness.

5. The method of claim 4 wherein forming the graded SiGe film includes forming a graded SiGe film with a bottom layer having a TEC about equal to the first TEC.

6. The method of claim 4 wherein forming the graded SiGe film includes forming a graded SiGe film with a top layer having a TEC about equal to the second TEC.

7. The method of claim 4 wherein forming the graded SiGe film includes forming a graded SiGe film with a TEC responsive to the Ge content in the graded SiGe film.

8. The method of claim 1 wherein forming the SiGe film includes forming a SiGe film having a thickness in a range of about 200 nm to 500 nm; and,
the method further comprising:
implanting ions into the SiGe film selected from a group consisting of helium and hydrogen; and,
relaxing the SiGe film in response to the ion implantation.

9. The method of claim 8 wherein implanting ions into the SiGe film includes implanting H2⁺with:
a dosage in a range of 2×10¹⁴ cm⁻² to 2×10¹⁶ cm⁻²; and, an energy in a range of about 10 keV to 100 keV.

10. The method of claim 1 wherein forming the buffer layer includes depositing the buffer layer using a process selected from a group consisting of metalorganic chemical vapor deposition (MOCVD), hydride vapor phase epitaxy (HVPE), and molecular beam epitaxy (MBE).

11. The method of claim 1 wherein forming the SiGe film includes forming a SiGe film with a relaxed top layer of SiGe.

12. The method of claim 1 wherein depositing the GaN film includes depositing GaN using a process selected from a group consisting of MOCVD, HVPE, and MBE.
